(19) United States
(12) Patent Application Publication
(10) Pub. No.: US 2023/0006054 A1
(43) Pub. Date: Jan. 5, 2023

(54) TUNNEL FIELD EFFECT TRANSISTOR AND TERNARY INVERTER INCLUDING THE SAME

(71) Applicant: UNIST(ULSAN NATIONAL INSTITUTE OF SCIENCE AND TECHNOLOGY), Ulsan (KR)

(72) Inventors: Kyung Rok Kim, Ulsan (KR); Ji Won Chang, Ulsan (KR); Jae Won Jeong, Ulsan (KR); Youngeun Choi, Ulsan (KR); Wooseok Kim, Ulsan (KR)

(73) Assignee: UNIST(ULSAN NATIONAL INSTITUTE OF SCIENCE AND TECHNOLOGY), Ulsan (KR)

(21) Appl. No.: 17/673,766

(22) Filed: Feb. 16, 2022

(30) Foreign Application Priority Data
Jun. 30, 2021 (KR) 10-2021-0085769

(51) Int. Cl. H01L 29/66; H01L 27/092; H01L 29/786

(52) U.S. Cl. CPC H01L 29/66977; H01L 27/0928; H01L 29/78618

(57) ABSTRACT

A tunnel field effect transistor includes a source region and a drain region, positioned on a substrate, a channel region positioned between the source region and the drain region and having a first length in a first direction, a gate electrode positioned on the channel region, and a gate insulating layer positioned between the channel region and the gate electrode, wherein the source region is doped with impurities of a first conductivity type and the drain region is doped with impurities of a second conductivity type that is different from the first conductivity type, and one of the source region and the drain region includes an extension region extending toward the other region, the extension region being positioned under the channel region to form a constant current independent of a gate voltage of the gate electrode.

### CROSS-REFERENCE TO RELATED APPLICATION

This application is based on and claims priority under 35 U.S.C. § 119 to Korean Patent Application No. 10-2021-0085769, filed on Jun. 30, 2021, in the Korean Intellectual Property Office, the disclosure of which is incorporated by reference herein in its entirety.

### BACKGROUND

### 1. Field

The disclosure relate to a tunnel field effect transistor and a ternary inverter including the same.

### 2. Description of the Related Art

Conventional binary logic-based digital systems have focused on increasing the bit density of information through scaling of complementary metal-oxide semiconductor (CMOS) devices in order to quickly process large amounts of data. However, with the recent integration to less than 30 nanometers (nm), there has been a limitation in increasing bit density due to an increase in leakage current and power consumption caused by a quantum tunneling effect. In order to overcome this bit density limitation, interest in ternary logic elements and circuits, which are multi-valued logics, is rapidly increasing. In particular, the development of a standard ternary inverter (STI) as a basic unit for implementing ternary logic has been actively carried out. However, unlike an existing binary inverter that uses two CMOS for one voltage source, conventional techniques related to the STI require more voltage sources, require a complex circuit configuration, or have a complicated manufacturing process.

In the ternary data processing of the STI, the current characteristics of two components, that is, a current component dependent on a gate voltage and a constant current component independent of the gate voltage, are used. In the case of the conventional STI device, a gate-dependent current is implemented by the thermal diffusion mechanism of a CMOS device, and a gate-independent constant current is implemented by the quantum mechanical interband tunneling mechanism in a PN junction. A conventional CMOS device-based STI process implements the gate-dependent current on the same principle as CMOS, and thus, there is a limitation in the switching capability due to the characteristics of the thermal diffusion mechanism. In order to further improve the ultra-low power characteristics of ternary devices, operating voltage scaling is essential, and for this purpose, a technique capable of overcoming limitations of the conventional switching capability is required.

### SUMMARY

One or more embodiments include a tunnel field effect transistor capable of not only improving switching capability but also promoting process simplification, and a ternary inverter having constant current characteristics and ultra-low power characteristics by using the tunnel field effect transistor.

Additional aspects will be set forth in part in the description which follows and, in part, will be apparent from the description, or may be learned by practice of the presented embodiments of the disclosure.

According to one or more embodiments, a tunnel field effect transistor includes a source region and a drain region, positioned on a substrate, a channel region positioned between the source region and the drain region and having a first length in a first direction, a gate electrode positioned on the channel region, and a gate insulating layer positioned between the channel region and the gate electrode, wherein the source region is doped with impurities of a first conductivity type and the drain region is doped with impurities of a second conductivity type that is different from the first conductivity type, and one of the source region and the drain region includes an extension region extending toward the other region, the extension region being positioned under the channel region to form a constant current independent of a gate voltage of the gate electrode.

An upper surface of the extension region may be apart from an upper surface of the channel region by a certain distance in a second direction intersecting with the first direction.

The source region may include a first extension region as the extension region, wherein the first extension region may have an extension width in the first direction and the extension width may be less than or equal to the first length of the channel region.

The first extension region may have the same type of conductivity as the first conductivity type.

The first extension region may have the same type of conductivity as the second conductivity type, wherein a doping concentration of the first extension region may be lower than a doping concentration of the drain region.

The drain region may include a second extension region as the extension region, wherein the second extension region may have an extension width in the first direction and the extension width may be less than or equal to the first length of the channel region.

The second extension region may have the same type of conductivity as the second conductivity type.

The second extension region may have the same type of conductivity as the first conductivity type, wherein a doping concentration of the second extension region may be lower than a doping concentration of the source region.

According to one or more embodiments, a ternary inverter includes: a first well region and a second well region arranged parallel to the first well region in a first direction; a first source region, a first channel region, and a first drain region, positioned on the first well region, and a first gate electrode positioned on the first channel region; and a second source region, a second channel region, and a second drain region, positioned on the second well region, and a second gate electrode positioned on the second channel region, wherein the first source region and the first drain region are respectively doped with impurities of different conductivity types, and the second source region and the second drain region are respectively doped with impurities of different conductivity types, wherein one of the first source region and the first drain region includes a first extension region extending toward the other region, one of the second source region and the second drain region includes a second extension region extending toward the other region, and the first extension region and the second extension region are respectively positioned under the first channel region and the second channel region and respectively form constant currents independent of a gate voltage.

When the first extension region is in direct contact with the first source region and the second extension region is in direct contact with the second source region, the first source region and the first extension region may be doped with impurities of a first conductivity type, the first drain region may be doped with impurities of a second conductivity type that is different from the first conductivity type, the second source region and the second extension region may be doped with impurities of the second conductivity type, and the second drain region may be doped with impurities of the first conductivity type.

When the first extension region is in direct contact with the first drain region and the second extension region is in direct contact with the second drain region, the first source region may be doped with impurities of a first conductivity type, the first drain region and the first extension region may be doped with impurities of a second conductivity type that is different from the first conductivity type, the second source region may be doped with impurities of the second conductivity type, and the second drain region and the second extension region may be doped with impurities of the first conductivity type.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of a tunneling field effect transistor according to an embodiment of the disclosure;

FIG. 2 is a view for explaining an operation of a tunnel field effect transistor according to an embodiment of the disclosure;

FIG. 3 illustrates gate voltage-drain current graphs of NMOS transistors according to an embodiment of the disclosure and existing NMOS transistors;

FIG. 4 illustrates gate voltage-drain current graphs of PMOS transistors according to an embodiment of the disclosure and existing PMOS transistors;

FIG. 5 is a circuit diagram of a ternary inverter according to an embodiment of the disclosure;

FIG. 6 is a cross-sectional view of a ternary inverter according to an embodiment of the disclosure;

FIG. 7 is a cross-sectional view of a tunneling field effect transistor according to another embodiment of the disclosure;

FIG. 8 is a cross-sectional view of a tunneling field effect transistor according to another embodiment of the disclosure;

FIG. 9 illustrates gate voltage-drain current graphs of ternary inverters according to an embodiment of the disclosure and existing binary inverters;

FIG. 10 illustrates input voltage (V_{IN})-output voltage (V_{OUT}) graphs of a ternary inverter according to an embodiment of the disclosure and an existing binary inverter;

FIG. 11 illustrates gate voltage-drain current graphs of a tunneling field effect transistor according to an embodiment of the disclosure and an existing NMOS transistor;

FIG. 12 is a gate voltage-drain current graph according to a drain voltage of a tunneling field effect transistor according to an embodiment of the disclosure; and

FIG. 13 is a graph showing input/output voltage characteristics of a ternary inverter according to another embodiment of the disclosure.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

As the present disclosure allows for various changes and numerous embodiments, particular embodiments will be illustrated in the drawings and described in detail in the written description. The attached drawings for illustrating one or more embodiments are referred to in order to gain a sufficient understanding, the merits thereof, and the objectives accomplished by the implementation. However, the embodiments may have different forms and should not be construed as being limited to the descriptions set forth herein.

The example embodiments will be described below in more detail with reference to the accompanying drawings. Those components that are the same or are in correspondence are rendered the same reference numeral regardless of the figure number, and redundant explanations are omitted.

It will be understood that although the terms “first,” “second,” etc. may be used herein to describe various components, these components should not be limited by these terms. These components are only used to distinguish one component from another.

Hereinafter, what is described as “above” or “on” may include not only directly on in contact, but also on non-contacting.

As used herein, the singular forms “a,” “an,” and “the” are intended to include the plural forms as well, unless the context clearly indicates otherwise. It will be further understood that the terms “include”, “have”, “including”, and/or “having” used herein specify the presence of stated features or components, but do not preclude the presence or addition of one or more other features or components.

Sizes of elements in the drawings may be exaggerated for convenience of explanation. In other words, since sizes and thicknesses of components in the drawings are arbitrarily illustrated for convenience of explanation, the following embodiments are not limited thereto.

In addition, a term such as “ . . . portion” or “ . . . region” may mean a unit for processing at least one function or operation.

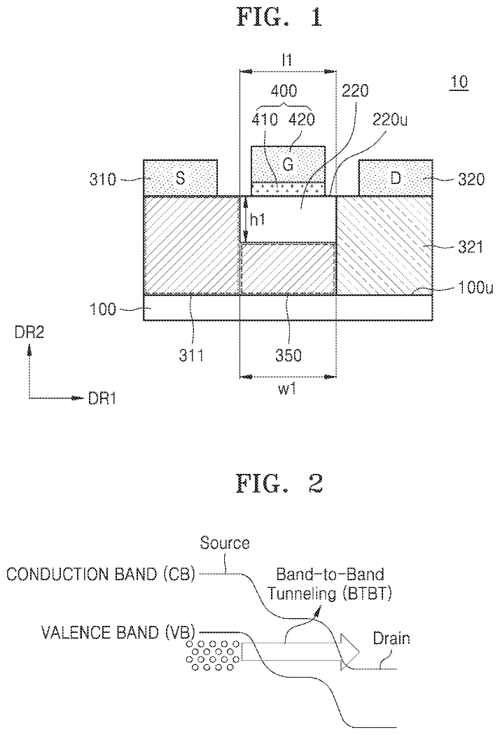

FIG. 1 is a cross-sectional view of a tunneling field effect transistor (hereinafter, may be referred to as a ‘TFET’) according to an embodiment of the disclosure.

Referring to FIG. 1, a TFET 10 according to an embodiment may include a substrate 100, a source region 311, a drain region 321, a channel region 220, and a gate structure 400. In this case, at least one of the source region 311 and the drain region 321 may include an extension region 350. According to an embodiment, the TFET 10 may further include a source electrode 310 and a drain electrode 320.

The substrate 100 may be a semiconductor substrate. The substrate 100 may include silicon (Si). The substrate 100 may include group III to V compound semiconductor materials. The substrate 100 may have semiconductor properties enhanced by using a material having a narrow band gap characteristic of a band gap of about 1 eV or less, and the material may be a single element semiconductor material or a compound semiconductor material. For example, the material may include at least one of Ge, SiGe, InGaAs, and InAs at 300 K. In this case, the substrate 100 may include a combination of one or more of the above materials or may include a heterojunction, and the type of the substrate 100 does not limit the disclosure.

The substrate 100 may be of a first conductivity type. For example, the first conductivity type may be n-type or p-type. Men the conductivity type of the substrate 100 is n-type, the substrate 100 may include a group V element (e.g., P or As) as an impurity. Men the conductivity type of the substrate 100 is p-type, the substrate 100 may include a group III element (e.g., B or In) as an impurity. Hereinafter, a region having an n-type conductivity may include a group V element (e.g., P or As) as an impurity, and a region having a p-type conductivity may include a group III element (e.g., B and In) as an impurity. Hereinafter, the first conductivity type or the second conductivity type may correspond to an n-type or a p-type. For example, it means that, when the first conductivity type is n-type, the second conductivity type is p-type and when the first conductivity type is p-type, the second conductivity type is n-type.

The source region 311, the drain region 321, and the extension region 350 may be positioned on the substrate 100. In this case, the extension region 350 may be a region in any one of the source region 311 and the drain region 321. The source region 311 and the drain region 321 may be apart from each other in a first direction DR1 parallel to an upper surface 100u of the substrate 100. The source region 311 may be doped with impurities of a first conductivity type. The drain region 321 may be doped with impurities of a second conductivity type that is different from that of the source region 311. For example, when the first conductivity type is n-type, the second conductivity type may be p-type, and when the first conductivity type is p-type, the second conductivity type may be n-type.

The source region 311 and the drain region 321 may be electrically connected to the substrate 100. For example, the source region 311 and the drain region 321 may directly contact the substrate 100. An electric field may be formed between the drain region 321 and the substrate 100. The strength of the electric field may be, for example, about 10⁶ V/cm or more.

In this case, one of the source region 311 and the drain region 321 may include an extension region 350 extending toward the other region. The extension region 350 is positioned under the channel region 220, which will be described later, to form a constant current independent of the gate voltage of a gate electrode 420.

An upper surface of the extension region 350 may be apart from an upper surface 220u of the channel region 220 by a certain distance in a second direction DR2 intersecting with the first direction DR1. In this case, the certain distance may be a first height h1. For example, the first height h1 may be about 3 nm or more and about 1 μm or less. In other words, the extension region 350 may be arranged to be apart from the upper surface 220u of the channel region 220 by a certain distance in order to flow a gate-dependent current. Hereinafter, various embodiments of the extension region 350 will be described.

Hereinafter, a first embodiment in which the source region 311 includes the extension region 350 will be described.

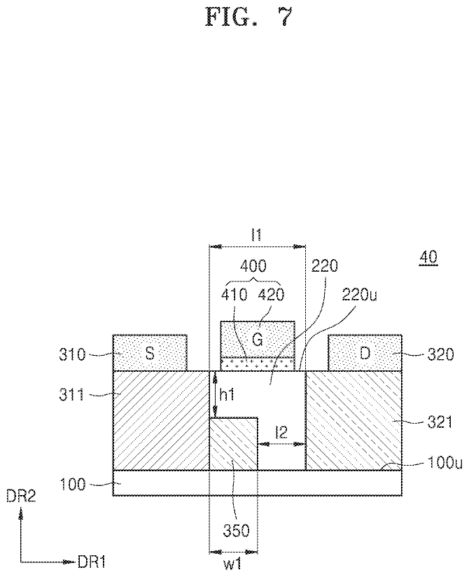

When the source region 311 includes the extension region 350, the extension region 350 is referred to as a first extension region. The first extension region may have an extension width w1 in the first direction DR1, and the extension width w1 may be less than or equal to a first length l1 of the channel region 220. In FIG. 1, a case in which the extension width w1 of the extension region 350 is equal to the first length l1 of the channel region 220 (w1=l1), that is, the extension region 350 and the drain region 321 directly contact each other is shown as an example. An embodiment in which the extension width w1 is less than the first length l1 (w1<l1) will be described in more detail with reference to FIG. 7 to be described later.

In particular, in the case of the first embodiment in which the source region 311 includes the extension region 350, the flow of the gate-dependent current may be further improved according to an overlapping length from the source region 311 toward the channel region 220, that is, the extension width w1.

For example, the first extension region, that is, the extension region 350, may have the same type of conductivity as that of the source region 311. For example, when the source region 311 is doped with impurities of the first conductivity type, the first extension region may also be doped with impurities of the first conductivity type in the same manner.

According to an embodiment, the first extension region may have a conductivity type that is different from that of the source region 311. This embodiment will be described in more detail with reference to FIG. 7 to be described later.

Next, a second embodiment in which the drain region 321 includes the extension region 350 will be described.

When the drain region 321 includes the extension region 350, the extension region 350 is referred to as a second extension region. A relationship between the extension width w1 of the second extension region and the first length l1 of the channel region 220 will be simply described because the same description as that given in the first embodiment described above may be applied to the second embodiment. The second extension region may have an extension width w1 in the first direction DR1, and the extension width w1 may be less than or equal to the first length l1 of the channel region 220.

For example, the second extension region, that is, the extension region 350, may have the same type of conductivity as that of the drain region 321. For example, when the drain region 321 is doped with impurities of the second conductivity type, the second extension region may also be doped with impurities of the second conductivity type in the same manner.

According to an embodiment, the second extension region may have a conductivity type that is different from that of the drain region 321. This embodiment will be described in more detail with reference to FIG. 7 to be described later.

The source electrode 310 may be positioned on the source region 311, and the drain electrode 320 may be positioned on the drain region 321. The source electrode 310 and the drain electrode 320 may each include an electrically conductive material. The source electrode 310 and the drain electrode 320 may each include the same material as the gate electrode 420 to be described later or may include different materials.

The channel region 220 may be disposed between the source region 311 and the drain region 321. The channel region 220 may include substantially the same material as the substrate 100. For example, the channel region 220 may include Si. The channel region 220 may be doped with impurities of the same first conductivity type as the substrate 100, and a doping concentration of the channel region 220 may be substantially the same as that of the substrate 100.

The channel region 220 may have the first length l1 in the first direction DR1. For example, the first length l1 may be less than or equal to about 10 nm.

A gate structure 400 may be positioned on the channel region 220. When viewed in the first direction DR1, the gate structure 400 may be positioned between the source region 311 and the drain region 321. For example, the gate structure 400 may partially overlap the source region 311 and the drain region 321 in the second direction DR2. The gate structure 400 may include a gate insulating layer 410 and a gate electrode 420. Although not shown in FIG. 1, the gate structure 400 may include other components such as a spacer.

The gate electrode 420 may include an electrically conductive material. For example, the gate electrode 420 may include a doped semiconductor material, a metal, an alloy, or a combination thereof. For example, the gate electrode 420 may include doped polysilicon, tungsten (W), titanium nitride (TiN), or a combination thereof.

The gate insulating layer 410 may be provided between the gate electrode 420 and the channel region 220. The gate insulating layer 410 may electrically insulate the gate electrode 420 and the channel region 220 from each other. For example, the gate insulating layer 410 may directly contact the upper surface of the channel region 220.

The gate insulating layer 410 may be provided between the gate electrode 420 and the channel region 220. For example, the gate insulating layer 410 may directly contact the channel region 220 and the gate electrode 420. The gate insulating layer 410 may include a material capable of realizing a desired capacitance. The gate insulating layer 410 may include a material having a high dielectric constant. The high dielectric constant may mean a dielectric constant that is higher than that of silicon oxide. In an embodiment, the gate insulating layer 410 may include a metal oxide including at least one metal selected from Ca, Sr, Ba, Sc, Y, La, Ti, Hf, Zr, Nb, Ta, Ce, Pr, Nd, Gd, Dy, Yb, and Lu. For example, the gate insulating layer 410 may include SiO₂, SION, HfO₂, ZrO₂, CeO₂, La₂O₃, Ta₂O₃, or TiO₂. The gate insulating layer 410 may have a single-layer structure or a multi-layer structure.

In an example, the threshold voltage of the tunnel field effect transistor 10 may be adjusted by a doping concentration of the substrate 100 and/or a work function of the gate electrode 420. For example, the work function of the gate electrode 420 may be controlled by the material of the gate electrode 420 or by an additional work function control layer (not shown). For example, an additional work function control layer may be between the gate insulating layer 410 and the substrate 100.

Although not shown in FIG. 1, a pair of isolation regions may be positioned on the substrate 100. The pair of isolation regions may be apart from each other in the first direction DR1. The pair of isolation regions may extend in the second direction DR2 perpendicular to the upper surface 100u of the substrate 100. For example, the thicknesses of the pair of isolation regions in the second direction DR2 may be greater than the thickness of the channel region 220 in the second direction DR2. The pair of isolation regions may include an electrically insulating material, for example, SiO₂ or a high-k material (e.g., SiON, HfO₂, or ZrO₂).

Hereinafter, the channel formation principle of the TFET 10 will be described with reference to FIG. 2. FIG. 2 is a view for explaining an operation of a tunnel field effect transistor according to an embodiment of the disclosure.

In the TFET 10, a channel may be formed by inter-band tunneling that occurs between the source region 311 and the channel region 220. A case in which the inter-band tunneling occurs may be defined as a case in which the TFET 10 has an on state. Conversely, a case in which the inter-band tunneling does not occur may be defined as a case in which the TFET 10 has an off state. When the TFET 10 is an NMOS transistor, the conductivity type of the drain region 321 may be N-type. Conversely, when the TFET 10 is a PMOS transistor, the conductivity type of the drain region 321 may be P-type.

The extension region 350 of one of the source region 311 and the drain region 321 may form a constant current between the drain region 321 and the substrate 100. As described below with reference to FIG. 2, the constant current may be a band-to-band tunneling (BTBT) current flowing between the drain region 321 and the substrate 100. The constant current may be independent from a gate voltage applied to the gate electrode 420. That is, the constant current may flow regardless of the gate voltage. When the TFET 10 is an NMOS transistor, a constant current may flow from the drain region 321 to the substrate 100. Conversely, when the TFET 10 is a PMOS transistor, a constant current may flow from the substrate 100 to the drain region 321. Referring to FIG. 2, the constant current may be implemented by direct tunneling between the source region 311 and the drain region 321.

According to an embodiment of the disclosure, a doped region (i.e., the extension region 350) in which either the source region 311 or the drain region 321 is extended toward an opposite region may be formed, and thus, the TFT 10 that forms a constant current independent of the gate voltage may be provided. As described above, according to embodiments of the disclosure, even without forming an additional constant current forming layer, a constant current may be implemented through the extension region 350 provided at the same time as the source region 311 or the drain region 321 is formed, thereby achieving process simplification. In addition, as in the embodiment of the disclosure, by using a TFET including the extension region 350 and having a source and a drain having different conductivity types, a steep slope characteristic between a drain current of the TFET and a gate voltage thereof may be secured, thereby improving switching capability.

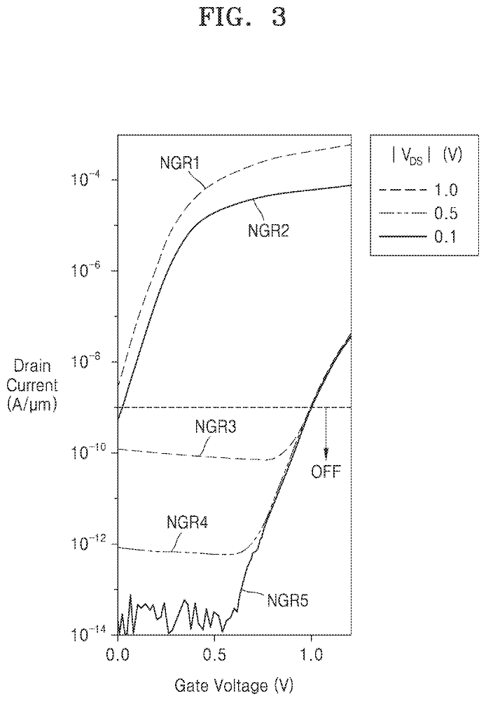

FIG. 3 illustrates gate voltage-drain current graphs of NMOS transistors according to an embodiment of the disclosure and existing NMOS transistors.

Referring to FIG. 3, gate voltage-drain current graphs NGR1 and NGR2 of the existing NMOS transistors and gate voltage-drain current graphs NGR3, NGR4, and NGR5 of the NMOS transistors according to an embodiment of the disclosure are shown.

The drain current of each of the existing NMOS transistors does not have a constant current component that flows regardless of the gate voltage of the existing NMOS transistor.

The drain current of each of the NMOS transistors according to an embodiment of the disclosure has a constant current component that flows regardless of the gate voltage of the NMOS transistor. For example, it may be confirmed that a constant current flows through each of the NMOS transistors according to an embodiment of the disclosure even when each of the NMOS transistors has an off state.

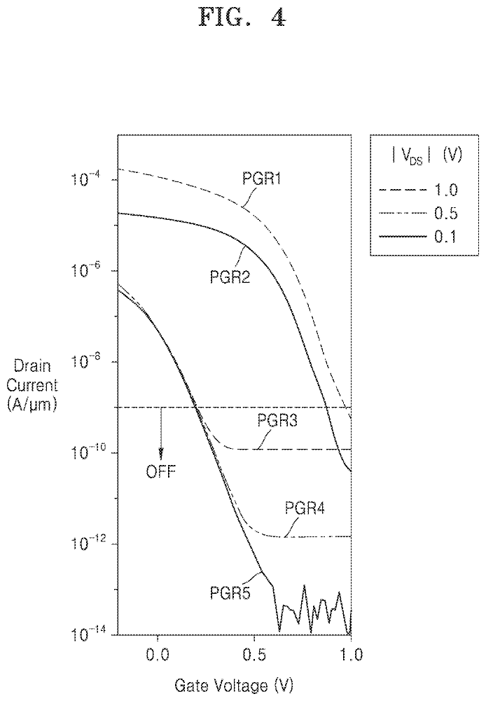

FIG. 4 illustrates gate voltage-drain current graphs of PMOS transistors according to an embodiment of the disclosure and existing PMOS transistors.

Referring to FIG. 4, gate voltage-drain current graphs PGR1 and PGR2 of the existing PMOS transistors and gate voltage-drain current graphs PGR3, PGR4, and PGR5 of the PMOS transistors according to an embodiment of the disclosure are shown.

The drain current of each of the existing PMOS transistors does not have a constant current component that flows regardless of the gate voltage of the existing PMOS transistor.

The drain current of each of the PMOS transistors according to an embodiment of the disclosure has a constant current component that flows regardless of the gate voltage of the PMOS transistor. For example, it may be confirmed that a constant current flows through each of the PMOS transistors according to an embodiment of the disclosure even when each of the PMOS transistors has an off state.

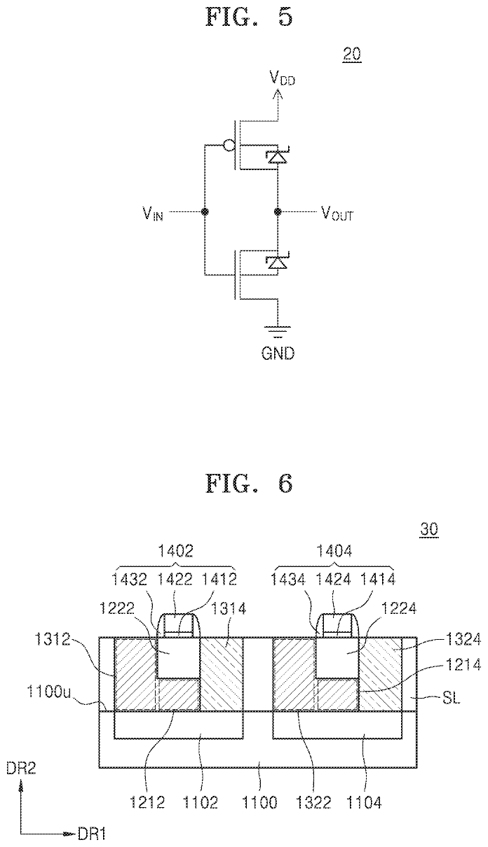

FIG. 5 is a circuit diagram of a ternary inverter 20 according to an embodiment of the disclosure. Descriptions overlapping with those given with reference to FIG. 1 may be simplified or omitted.

Referring to FIG. 5, the ternary inverter 20 according to an embodiment of the disclosure may include an NMOS transistor (hereinafter, referred to as an ‘N-type TFET’) and a PMOS transistor (hereinafter, referred to as a ‘P-type TFET’). Each of the N-type TFET and the P-type TFET may be substantially the same device as the TFET 10 described with reference to FIG. 1. The conductivity type of the substrate 100, the source region 311, and the channel region 220 of the N-type TFET may be p-type, and the conductivity type of the drain region 321 of the N-type TFET may be n-type. Conversely, the conductivity type of the substrate 100, the source region 311, and the channel region 220 of the P-type TFET may be n-type, and the conductivity type of the drain region 321 of the P-type TFET may be p-type.

A ground voltage GND may be applied to the source and substrate of the N-type TFET. Hereinafter, for brevity of explanation, it is assumed that the ground voltage is 0 volts (V). A driving voltage Vo may be applied to the source and substrate of the P-type TFET. An input voltage V_{IN} may be applied to each of the gate electrode of the N-type TFET and the gate electrode of the P-type TFET.

The drain of the N-type TFET may be electrically connected to the drain of the P-type TFET, and thus, the drain of the N-type TFET and the drain of the P-type TFET may have the same voltage. The voltage of the drains of the N-type TFET and the P-type TFET may be an output voltage V_{OUT} of the ternary inverter 20.

A constant current may flow from the drain of the N-type TFET to the substrate thereof. A constant current may flow from the substrate of the P-type TFET to the drain thereof. The constant currents may be independent of the input voltage V_{IN}.

In an example, a first input voltage may be applied to the gate electrode of the P-type TFET and the gate electrode of the N-type TFET such that the P-type TFET has a constant current dominating a channel current and the N-type TFET has a channel current dominating a constant current. In this case, the output voltage V_{OUT} of the ternary inverter 20 may be a first voltage.

In another example, a second input voltage may be applied to the gate electrode of the P-type TFET and the gate electrode of the N-type TFET such that the N-type TFET has a constant current dominating the channel current and the P-type TFET has a channel current dominating the constant current. In this case, the output voltage V_{OUT} of the ternary inverter 20 may be a second voltage greater than the first voltage.

In another example, a third input voltage may be applied to the gate electrode of the P-type TFET and the gate electrode of the N-type TFET such that each of the N-type TFET and the P-type TFET has a constant current dominating the channel current. In this case, the output voltage V_{OUT} of the ternary inverter 20 may be a third voltage between the first voltage and the second voltage.

The constant current flowing from the drain of the N-type TFET to the substrate thereof and the constant current flowing from the substrate of the P-type TFET to the drain thereof may flow regardless of gate voltages applied to the gate electrodes of the P-type TFET and the N-type TFET. A current in the ternary inverter 20 may flow from the substrate of the P-type TFET to the substrate of the N-type TFET through the drain of the P-type TFET and the drain of the N-type TFET. The driving voltage V_{DD} applied to the substrate of the P-type TFET may be divided between the resistance between the substrate of the P-type TFET and the drain of the P-type TFET and the resistance between the substrate of the N-type TFET and the drain of the N-type TFET. The output voltage V_{OUT} may be a voltage applied to the resistance between the substrate of the N-type TFET and the drain of the N-type TFET. The output voltage V_{OUT} may have a value between the driving voltage V_{DO} and 0 V.

The output voltage V_{OUT} may have 0 V (a ‘0’ state), a voltage (a ‘1’ state) between the driving voltage V_{DD} and 0 V, or the driving voltage V_{DD} (a ‘2’ state) according to the input voltage V_{IN}. The disclosure may provide the ternary inverter 20 having three states according to the input voltage V_{IN}.

FIG. 6 is a cross-sectional view of a ternary inverter 30 according to an embodiment of the disclosure. Descriptions overlapping with those given with reference to FIG. 1 may be omitted or simplified.

Referring to FIG. 6, the ternary inverter 30 according to an embodiment of the disclosure may include a substrate 1100, a first well region 1102, a second well region 1104, an isolation layer SL, a first channel region 1222, a second channel region 1224, a first source region 1312, a first drain region 1314, a second source region 1322, a second drain region 1324, a first gate structure 1402, and a second gate structure 1404.

The substrate 1100 may be a semiconductor substrate. For example, the substrate 1100 may include Si. The substrate 1100 may be an intrinsic semiconductor substrate or a semiconductor substrate having a conductivity type.

The first well region 1102 and the second well region 1104 may be provided in an upper portion of the substrate 1100. The first well region 1102 and the second well region 1104 may be apart from each other in a first direction DR1 parallel to an upper surface 1100u of the substrate 1100. The first well region 1102 may be a p-type region. The second well region 1104 may be an n-type region.

The isolation layer SL exposing the first well region 1102 and the second well region 1104 may be provided on the substrate 1100. The isolation layer SL may include substantially the same material as the pair of isolation regions described with reference to FIG. 1.

The first source region 1312 and the first drain region 1314 may be positioned on the first well region 1102, and the first channel region 1222 may be positioned between the first source region 1312 and the first drain region 1314. Similarly, the second source region 1322 and the second drain region 1324 may be positioned on the second well region 1104, and the second channel region 1224 may be positioned between the second source region 1322 and the second drain region 1324.

In FIG. 6, a first embodiment in which the source regions 1312 and 1322 include extension regions 1212 and 1214, respectively is illustrated. In this case, the extension regions 1212 and 1214 may have the same conductivity type as the source regions 1312 and 1324. In addition, the same descriptions as those given in the embodiment described above may be applied to an embodiment related to the extension regions 1212 and 1214.

The first channel region 1222 may be an epitaxial layer. For example, the first channel region 1222 may include Si. The conductivity type of the first channel region 1222 may be substantially the same as that of the substrate 1100 or the extension region 1212. For example, when the conductivity type of the substrate 1100 is p-type, the conductivity type of the first channel region 1222 may be p-type, and the doping concentration of the first channel region 1222 may be lower than that of the extension region 1212. As another example, when the conductivity type of the substrate 1100 is n-type, the conductivity type of the first channel region 1222 may be n-type, and the doping concentration of the first channel region 1222 may be lower than that of the extension region 1212. For example, the doping concentration of the first channel region 1222 may be substantially the same as the doping concentration of the first well region 1102.

The second channel region 1224 may be an epitaxial layer. For example, the second channel region 1224 may include Si. The conductivity type of the second channel region 1224 may be substantially the same as the conductivity type of the substrate 1100 or the extension region 1214. The conductivity type of the second channel region 1224 may be n-type, and the doping concentration of the second channel region 1224 may be lower than that of the extension region 1214. For example, the doping concentration of the second channel region 1224 may be substantially the same as the doping concentration of the second well region 1104.

The first source region 1312 may have the same conductivity type as the extension region 1212. The conductivity type of the first source region 1312 may be p-type. The doping concentration of the first source region 1312 may be higher than the doping concentration of the extension region 1212. The first drain region 1314 may have a conductivity type that is different from that of the extension region 1212. The conductivity type of the first drain region 1314 may be n-type.

The second source region 1322 may have the same conductivity type as the extension region 1214. The second source region 1322 may have an n-type conductivity. The doping concentration of the second source region 1322 may be higher than the doping concentration of the extension region 1214. The second drain region 1324 may have a conductivity type that is different from that of the extension region 1214. The conductivity type of the second drain region 1324 may be p-type.

The first gate structure 1402 may be provided on the first channel region 1222. The first gate structure 1402 may include a first gate insulating layer 1412, a first gate electrode 1422, and a first pair of spacers 1432. The first gate insulating layer 1412, the first gate electrode 1422, and the first pair of spacers may be substantially the same as the gate insulating layer 410, the gate electrode 420, and the pair of spacers, described with reference to FIG. 1, respectively.

The second gate structure 1404 may be provided on the second channel region 1224. The second gate structure 1404 may include a second gate insulating layer 1414, a second gate electrode 1424, and a second pair of spacers (1434). The second gate insulating layer 1414, the second gate electrode 1424, and the second pair of spacers (not shown) may be substantially the same as the gate insulating layer 410, the gate electrode 420, and the pair of spacers, described with reference to FIG. 1, respectively.

An embodiment of the disclosure may provide a ternary inverter 30 including the transistors described above. The first well region 1102, the extension region 1212, the first channel region 1222, the first source region 1312, the first drain region 1314, and the first gate structure 1402 may constitute an N-type TFET. The second well region 1104, the extension region 1214, the second channel region 1224, the second source region 1322, the second drain region 1324, and the second gate structure 1404 may constitute a P-type TFET. A ground voltage may be applied to the first well region 1102 and the source of the N-type TFET. A driving voltage may be applied to the second well region 1104 and the source of the P-type TFET. An input voltage V_{IN} may be applied to each of the first gate electrode 1422 of the N-type TFET and the second gate electrode 1424 of the P-type TFET.

The drain (i.e., the first drain region 1314) of the N-type TFET and the drain (i.e., the second drain region 1324) of the P-type TFET may be electrically connected to each other. The voltage of the drain of the N-type TFET and the drain of the P-type TFET may be the output voltage V_{OUT} of the ternary inverter 30. The descriptions of the ternary inverter 30 may be substantially the same as those given with reference to FIG. 5.

FIG. 7 is a cross-sectional view of a TFET 40 according to another embodiment of the disclosure. Descriptions overlapping with those given in the embodiment of FIG. 1 described above will be omitted or simplified, and differences will be mainly described. The same components may be described using the same reference numerals.

Referring to FIG. 7, the TFET 40 according to an embodiment may include a substrate 100, a source region 311, a drain region 321, a channel region 220, and a gate structure 400.

The source region 311 and the drain region 321 may be respectively doped with impurities of different conductivity types. For example, when the source region 311 is doped with impurities of a first conductivity type or a second conductivity type, the drain region 321 may be doped with impurities of the second conductivity type or the first conductivity type.

In this case, one of the source region 311 and the drain region 321 may include an extension region 350. The extension region 350 is positioned under the channel region 220 to form a constant current independent of the gate voltage of a gate electrode 420.

An upper surface of the extension region 350 may be apart from an upper surface 220u of the channel region 220 by a first height h1 that is a certain distance in the second direction DR2.

In FIG. 7, an embodiment in which an extension width w1 of the extension region 350 in the first direction DR1 is less than a first length l1 of the channel region 220 is illustrated.

According to the embodiment of FIG. 7, the source region 311 may include the extension region 350 (hereinafter, may be referred to as a first extension region). That is, the extension region 350 may directly contact the source region 311.

For example, when the source region 311 has the first conductivity type and the drain region 321 has the second conductivity type, the first extension region may have the second conductivity type that is the same as that of the drain region 321. However, in this case, a doping concentration of the first extension region may be lower than that of the drain region 321 having the second conductivity type that is the same as that of the first extension region.

Unlike in FIG. 7, the drain region 321 may include the extension region 350 (hereinafter, may be referred to as a second extension region). That is, the extension region 350 may directly contact the drain region 321.

For example, when the source region 311 has the first conductivity type and the drain region 321 has the second conductivity type, the second extension region may be doped with impurities of the first conductivity type. However, in this case, a doping concentration of the second extension region may be lower than that of the source region 311 having the first conductivity type that is the same as that of the second extension region.

The first length l1 of the channel region 220 or a second length 12 obtained by subtracting the extension width w1 in the first direction DR1 from the first length l1 may be about 10 nm or less.

As described above, according to embodiments of the disclosure, the extension region 350 may be formed in the channel region 220 during a doping process for forming the source region 311 or the drain region 321 to improve the electrical connectivity between the source region 311 and the drain region 321, and thus, a constant current independent of the gate voltage may be implemented and process simplification may be achieved. At the same time, by forming the extension region 350 to be apart from the surface of the channel region 220, the slope characteristic of a gate-dependent current may be secured, thereby improving switching capability and securing a low power characteristic.

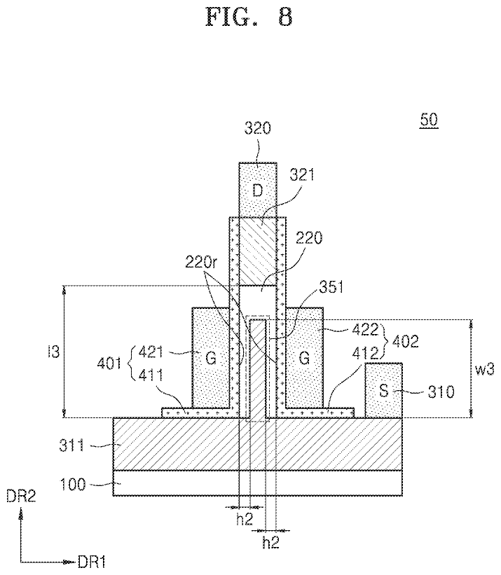

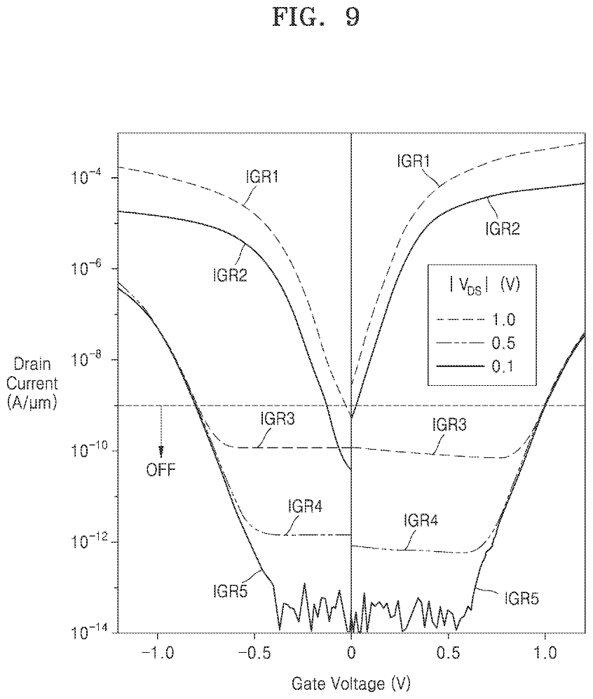

FIG. 8 is a cross-sectional view of a TFET 50 according to another embodiment of the disclosure. Descriptions that are substantially the same as those given in the embodiments described above may be omitted or simplified, and differences will be mainly described. The same components may be described using the same reference numerals.

Referring to FIG. 8, the TFET 50 according to an embodiment may be a vertical TFET. The TFET 50 according to an embodiment may include a substrate 100, a source region 311, a drain region 321, and gate structures 401 and 402. However, in the embodiment of FIG. 8, the source region 311 may extend in the first direction DR1, and the source region 311 and the drain region 321 may be apart from each other in the second direction DR2.

The source region 311 may include an extension region 351. The extension area 351 may have an extension width w3 in the second direction DR2. In FIG. 8, an embodiment in which the extension width w3 is less than a length 13 of the channel region 220 in the second direction DR2 is illustrated.

When the extension region 350 is positioned to extend in the second direction DR2, left and right sides of the extension region 350 may be apart from left and right surfaces 220r of the channel region 220 by a second height h2.

As described above, the extension region 350 may improve the electrical connectivity between the source region 311 and the drain region 321, thereby forming a gate-independent constant current through inter-band tunneling without a separate layer and achieving process simplification. At the same time, by forming the channel region 220 and the extension region 350 to be apart from each other, the flow of a gate-dependent current may be improved, and accordingly, the switching capability and low power characteristics of a device may be secured.

The gate structures 401 and 402 may be positioned to surround the channel region 220 (a gate all around (GAA) structure), and FIG. 8 is a cross-sectional view of the GAA structure in which the gate structures 401 and 402 may appear to be positioned on both sides with respect to the channel region 220. The gate structures 401 and 402 may overlap a portion of the source region 311 arranged in parallel with the substrate 100 with respect to the channel region 220, and both sides of the channel region 220. The gate structure 401 may include a gate insulating layer 411 and a gate electrode 421, and the gate structure 402 may include a gate insulating layer 412 and a gate electrode 422. The gate insulating layers 411 and 412 are in direct contact with a portion of the source region 311 at both sides of the channel region 220, and with both sides of the channel region 220 adjacent thereto, and thus electrically insulate the source region 311 and the channel region 220 from the gate electrodes 421 and 422.

FIG. 9 illustrates gate voltage-drain current graphs of ternary inverters according to an embodiment of the disclosure and existing binary inverters.

Referring to FIG. 9, gate voltage-drain current graphs IGR1 and IGR2 of the existing binary inverters and gate voltage-drain current graphs IGR3, IGR4, and IGR5 of the ternary inverters according to an embodiment of the disclosure.

The drain current of each of the existing binary inverters does not have a constant current component flowing regardless of the gate voltage of the existing binary inverter.

The drain current of each of the ternary inverters according to an embodiment of the disclosure has a constant current component flowing regardless of the gate voltage of the ternary inverter. For example, it may be confirmed that a constant current flows through each of the ternary inverters according to an embodiment of the disclosure even when each of the ternary inverters has an off state.

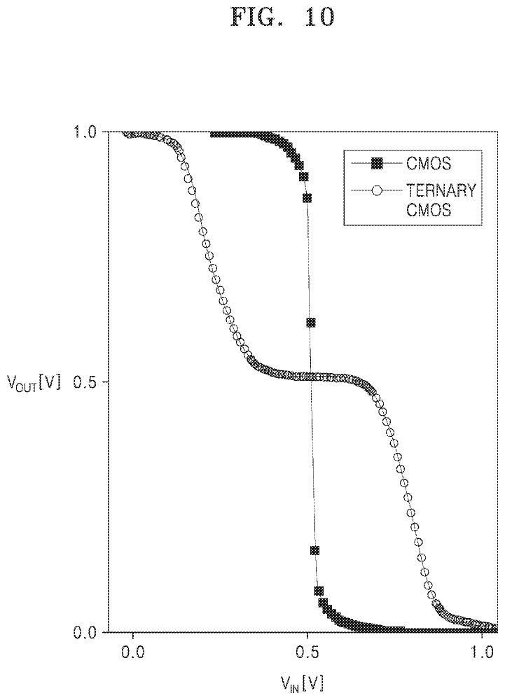

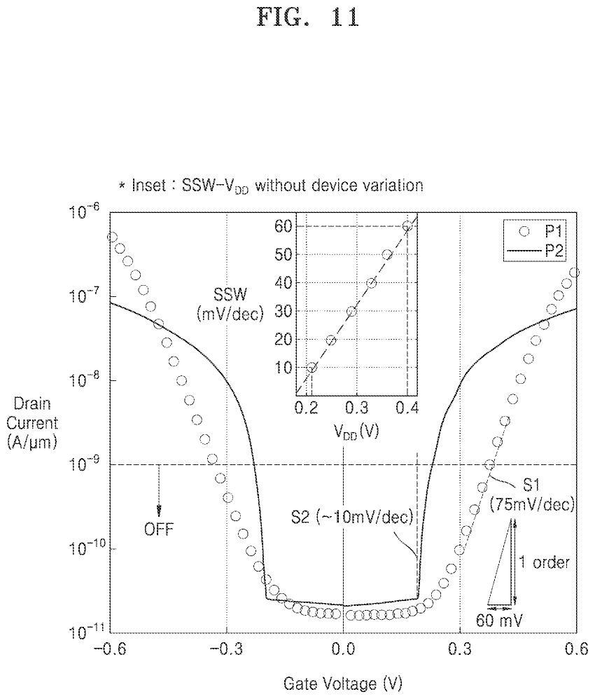

FIG. 10 illustrates input voltage (V_{IN})-output voltage (V_{OUT}) graphs of a ternary inverter according to an embodiment of the disclosure and an existing binary inverter.

Referring to FIG. 10, a driving voltage V_{DD} of each of the ternary inverter according to an embodiment and the existing binary inverter is 1.0 V, and a ground voltage thereof is 0 V. An input voltage V_{IN} of each of the ternary inverter and the existing binary inverter is 0 V to 1.0 V.

In the case of the existing binary inverter, when the input voltage V_{IN} is changed from 0 V to 1 V, an output voltage V_{OUT} of the existing binary inverter rapidly decreases from 1 V to 0 V in the vicinity of the input voltage V_{IN} of 0.5 V. That is, the existing binary inverter has two states (e.g., a ‘0’ state and a ‘1’ state).

In the case of the ternary inverter according to an embodiment of the disclosure, when the input voltage V_{IN} is changed from 0 V to 1 V, an output voltage V_{OUT} of the ternary inverter rapidly decreases from 1 V to 0.5 V and maintains 0.5 V, and then rapidly decreases from 0.5 V to 0 V. That is, the ternary inverter according to an embodiment of the disclosure has three states (e.g., a ‘0’ state, a ‘1’ state, and a ‘2’ state).

FIG. 11 illustrates gate voltage-drain current graphs of a TFET according to an embodiment of the disclosure and an existing NMOS transistor.

Referring to FIG. 11, a first profile P1 that is a gate voltage-drain current graph of the existing NMOS transistor and a second profile P2 that is a gate voltage-drain current graph of the TFET according to an embodiment of the disclosure are illustrated.

Referring to the first profile P1, the existing NMOS transistors has a constant current independent of the gate voltage thereof. That is, it may be confirmed that a constant current flows through the existing NMOS transistor even when the existing NMOS transistor is in an off state. However, the constant current flowing through the existing NMOS transistor may be implemented by thermal diffusion from the source region of the NMOS transistor to the drain region thereof because the source region and the drain region of the NMOS transistor have the same type of conductivity.

Referring to the second profile P2, the TFET according to an embodiment of the disclosure also has a constant current independent of the gate voltage thereof. That is, it may be confirmed that a constant current flows through the TFET even when the TFET is in an off state. However, the second profile P2 is different from the first profile P1 in that the constant current flowing in the TFET according to an embodiment of the disclosure is implemented by BTBT from the source region of the TFET to the drain region thereof as the source region and the drain region of the TFET have different types of conductivity.

An SSW-V_{DD} graph, which shows a value of subthreshold swing (SSW) according to an applied voltage, i.e., the driving voltage V_{DD}, is shown in the center of the graph of FIG. 11. SSW (mV/dec) may mean a voltage value required to increase a current value 10 times. In other words, a smaller SSW value means that a smaller voltage is required to obtain a desired current and thus required power consumption is also reduced. Reciprocal values of slopes, i.e., first and second swing values S1 and S2, shown on the right sides of the two profiles P1 and P2 mean the SSW values. The SSW-V_{DD} graph inserted in the center of the graph of FIG. 11 means V_{DD} according to the amount of SSW that may secure a static noise margin (SNM) of about 2 kBT/q to about 52 mV or more (‘kBT/q’ is ‘thermal’ voltage where kB is the Boltzmann constant, T is the temperature in degrees Kelvin, and q is the electronic charge.). In other words, a smaller SSW value means that a smaller V_{DD} may be implemented while maintaining the same SNM and operating voltage-scaling capability is improved.

The first swing value S1, which is a reciprocal value of a first slope, is shown on the right side of the first profile P1, and the first swing value S1 is, for example, measured to be about 75 mV/dec. The second swing value S2, which is a reciprocal value of a second slope, is shown on the right side of the second profile P2, and the second swing value S2 is, for example, measured to be about 10 mV/dec. Thus, it may be confirmed that the second swing value S2 in the second profile P2 is less than the first swing value SI in the first profile P1. In terms of slope, the slope of the second profile P2 is about 7.7 times the slope of the first profile P1, and thus, the TFET (i.e., the second profile P2) including the extension region 350 according to an embodiment of the disclosure has a steeper slope characteristic than the existing NMOS transistor (i.e., the first profile P1). That is, in the case of the TFET according to an embodiment of the disclosure, steeper slope characteristics of less than about 60 mV/dec may be secured, and accordingly, operating voltage-scaling capability may be improved in the TFET and an inverter including the TFET.

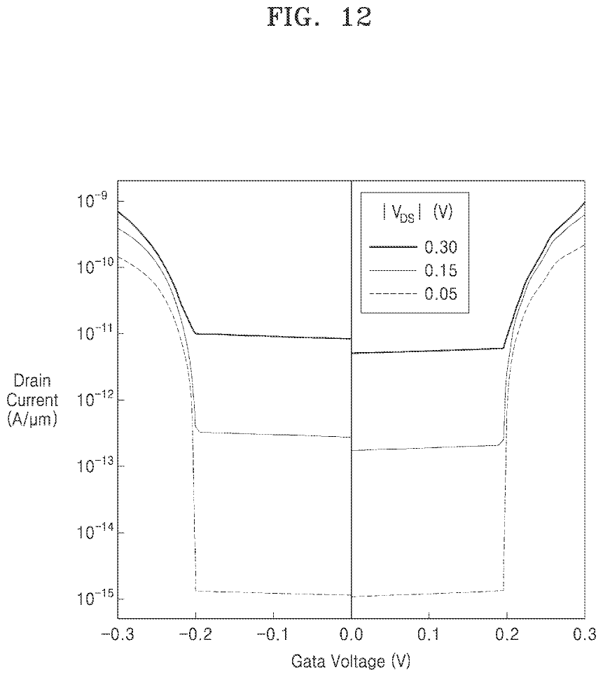

FIG. 12 is a gate voltage-drain current graph according to a drain voltage of a TFET according to an embodiment of the disclosure. Because FIG. 12 is a graph corresponding to the second profile P2 of FIG. 11, descriptions overlapping with those given with reference to FIG. 11 will be omitted.

Referring to FIG. 12, a gate voltage-drain current graph according to a drain voltage V_{DS} of the TFET according to an embodiment of the disclosure is shown. It may be confirmed that the TFET has a constant current independent of the gate voltage thereof and a swing value is less than about 60 mV/dec, which is a limit swing value by an existing CMOS heat dissipation diffusion mechanism and has a steep slope characteristic. In addition, it may be confirmed that the greater the drain voltage V_{DS}, the greater the constant current flowing through the TFET.

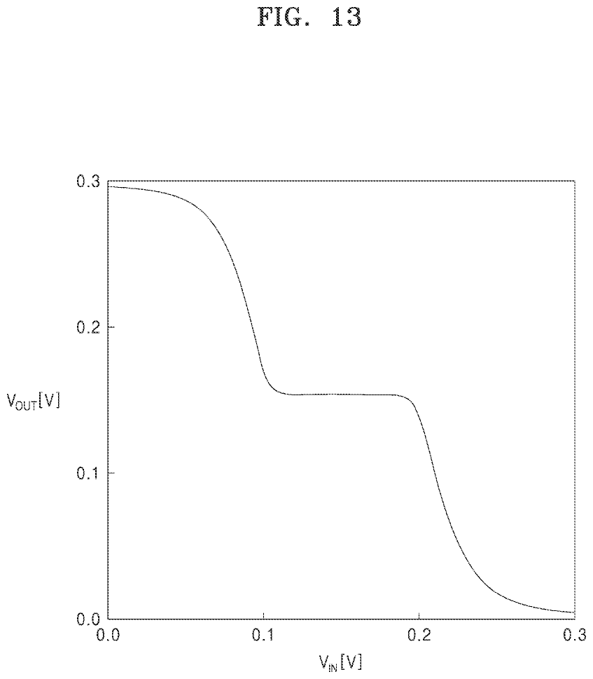

FIG. 13 is a graph showing input/output voltage characteristics of a ternary inverter according to another embodiment of the disclosure. Because FIG. 13 is a graph corresponding to the graph of FIG. 10, descriptions overlapping with those given with reference to FIG. 10 will be omitted, and features will be mainly described.

In the ternary inverter according to an embodiment of the disclosure, when an input voltage V_{IN} is changed from 0 V to 0.3 V, an output voltage V_{OUT} sharply decreases from 1 V to 0.15 V and maintains 0.15 V, and then sharply decreases from 0.15 V to 0 V. That is, it may be confirmed that the ternary inverter according to an embodiment of the disclosure has three states (e.g., a ‘0’ state, a ‘1’ state, and a ‘2’ state). However, a difference from the embodiment of FIG. 10 is that the range of each of the input voltage V_{IN} and the output voltage V_{OUT} is reduced from 0 V to 1 V to 0 V to 0.3 V due to a steeper slope of less than about 60 mV/dec, and thus, it may be confirmed that the operating voltage scaling capability of the ternary inverter according to an embodiment of the disclosure is improved.

According to embodiments of the disclosure, a TFET capable of not only improving switching capability but also promoting process simplification, and a ternary inverter having constant current characteristics and ultra-low power characteristics by using the TFET may be provided.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A tunnel field effect transistor comprising:
a source region and a drain region, positioned on a substrate;
a channel region positioned between the source region and the drain region and having a first length in a first direction;
a gate electrode positioned on the channel region; and
a gate insulating layer positioned between the channel region and the gate electrode,
wherein the source region is doped with impurities of a first conductivity type and the drain region is doped with impurities of a second conductivity type that is different from the first conductivity type, and one of the source region and the drain region includes an extension region extending toward the other region, the extension region being positioned under the channel region to form a constant current independent of a gate voltage of the gate electrode.

2. The tunnel field effect transistor of claim 1, wherein an upper surface of the extension region is apart from an upper surface of the channel region by a certain distance in a second direction intersecting with the first direction.

3. The tunnel field effect transistor of claim 2, wherein the source region includes a first extension region as the extension region,
wherein the first extension region has an extension width in the first direction and the extension width is less than or equal to the first length of the channel region.

4. The tunnel field effect transistor of claim 3, wherein the first extension region has a same type of conductivity as the first conductivity type.

5. The tunnel field effect transistor of claim 3, wherein the first extension region has a same type of conductivity as the second conductivity type, wherein a doping concentration of the first extension region is lower than a doping concentration of the drain region.

6. The tunnel field effect transistor of claim 2, wherein the drain region includes a second extension region as the extension region,
wherein the second extension region has an extension width in the first direction and the extension width is less than or equal to the first length of the channel region.

7. The tunnel field effect transistor of claim 6, wherein the second extension region has a same type of conductivity as the second conductivity type.

8. The tunnel field effect transistor of claim 6, wherein the second extension region has a same type of conductivity as the first conductivity type, wherein a doping concentration of the second extension region is lower than a doping concentration of the source region.

9. A ternary inverter comprising:
a first well region and a second well region arranged parallel to the first well region in a first direction;
a first source region, a first channel region, and a first drain region, positioned on the first well region, and a first gate electrode positioned on the first channel region; and
a second source region, a second channel region, and a second drain region, positioned on the second well region, and a second gate electrode positioned on the second channel region,
wherein the first source region and the first drain region are respectively doped with impurities of different conductivity types, and the second source region and the second drain region are respectively doped with impurities of different conductivity types,
wherein one of the first source region and the first drain region includes a first extension region extending toward the other region, one of the second source region and the second drain region includes a second extension region extending toward the other region, and the first extension region and the second extension region are respectively positioned under the first channel region and the second channel region and respectively form constant currents independent of a gate voltage.

10. The ternary inverter of claim 9, wherein, when the first extension region is in direct contact with the first source region and the second extension region is in direct contact with the second source region, the first source region and the first extension region are doped with impurities of a first conductivity type, the first drain region is doped with impurities of a second conductivity type that is different from the first conductivity type, the second source region and the second extension region are doped with impurities of the second conductivity type, and the second drain region is doped with impurities of the first conductivity type.

11. The ternary inverter of claim 9, wherein, when the first extension region is in direct contact with the first drain region and the second extension region is in direct contact with the second drain region, the first source region is doped with impurities of a first conductivity type, the first drain region and the first extension region are doped with impurities of a second conductivity type that is different from the first conductivity type, the second source region is doped with impurities of the second conductivity type, and the second drain region and the second extension region are doped with impurities of the first conductivity type.
